(19) United States
(12) Patent Application Publication
(10) Pub. No.: US 2025/0014957 A1
(43) Pub. Date: Jan. 9, 2025

(54) SEMICONDUCTOR PACKAGE HAVING INCREASED RELIABILITY

(71) Applicant: SAMSUNG ELECTRONICS CO., LTD., SUWON-SI (KR)

(72) Inventors: Jingu KIM, Suwon-si (KR); Gongje LEE, Suwon-si (KR); Yongjun LEE, Suwon-si (KR)

(21) Appl. No.: 18/762,040

(22) Filed: Jul. 2, 2024

(30) Foreign Application Priority Data
Jul. 5, 2023 (KR) 10-2023-0087408

(51) Int. Cl. H01L 23/31; H01L 23/00; H01L 23/14; H01L 23/26; H01L 23/29; H01L 23/49; H01L 23/498; H01L 25/00; H01L 25/10

(52) U.S. Cl. CPC H01L 23/3107; H01L 23/26; H01L 23/49822; H01L 24/24; H01L 25/105; H01L 23/14; H01L 23/29; H01L 23/49; H01L 23/49816; H01L 24/16; H01L 24/32; H01L 24/73; H01L 25/50; H01L 2224/16227; H01L 2224/24146; H01L 2224/32225; H01L 2224/73204; H01L 2225/1011

(57) ABSTRACT

A semiconductor package includes: a first redistribution structure including a first redistribution pattern and a first redistribution insulating layer at least partially surrounding the first redistribution pattern; a first semiconductor chip disposed on the first redistribution structure; a first molding member at least partially surrounding the first semiconductor chip and the first redistribution structure; a conductive pillar passing through the first molding member; a second redistribution structure disposed on the first molding member and including a second redistribution pattern and a second redistribution insulating layer at least partially surrounding the second redistribution pattern; a second semiconductor chip disposed on the second redistribution structure; and a second molding member at least partially surrounding the second semiconductor chip and the second redistribution structure.

### CROSS-REFERENCE TO RELATED APPLICATION

This application claims priority under 35 U.S.C. § 119 to Korean Patent Application No. 10-2023-0087408, filed on Jul. 5, 2023, in the Korean Intellectual Property Office, the disclosure of which is incorporated by reference herein in its entirety.

### TECHNICAL FIELD

The present inventive concept relates to a semiconductor package, and more particularly, to a semiconductor package having increased reliability.

### DISCUSSION OF THE RELATED ART

With the rapid increase in demand for portable devices in the electronic products market, electronic components incorporated into electronic products have continuously been desired to be compact and light. To make electronic components compact and light, a semiconductor package included in the electronic components is desired to be small in volume and to process a large amount of data. As semiconductor packages become increasingly compact and light, technology for protecting the inside of a semiconductor package from moisture is becoming increasingly desirable.

### SUMMARY

According to an embodiment of the present inventive concept, a semiconductor package includes: a first redistribution structure including a first redistribution pattern and a first redistribution insulating layer at least partially surrounding the first redistribution pattern; a first semiconductor chip disposed on the first redistribution structure; a first molding member at least partially surrounding the first semiconductor chip and the first redistribution structure; a conductive pillar passing through the first molding member; a second redistribution structure disposed on the first molding member and including a second redistribution pattern and a second redistribution insulating layer at least partially surrounding the second redistribution pattern; a second semiconductor chip disposed on the second redistribution structure; and a second molding member at least partially surrounding the second semiconductor chip and the second redistribution structure.

According to an embodiment of the present inventive concept, a semiconductor package includes: a first redistribution structure including a first redistribution pattern and a first redistribution insulating layer at least partially surrounding the first redistribution pattern; a first cover surrounding a side surface of the first redistribution structure; a first semiconductor chip disposed on the first redistribution structure; a first molding member disposed on the first redistribution structure and at least partially surrounding the first semiconductor chip; a conductive pillar passing through the first molding member; a second redistribution structure disposed on the first molding member and including a second redistribution pattern and a second redistribution insulating layer at least partially surrounding the second redistribution pattern; a second cover surrounding a side surface of the second redistribution structure; a second semiconductor chip disposed on the second redistribution structure; and a second molding member disposed on the second redistribution structure and at least partially surrounding the second semiconductor chip.

According to an embodiment of the present inventive concept, A semiconductor package includes: a first redistribution structure including a first redistribution pattern and a first redistribution insulating layer at least partially surrounding the first redistribution pattern; a first semiconductor chip disposed on the first redistribution structure; a fourth semiconductor chip disposed on the first redistribution structure and spaced apart from the first semiconductor chip in a horizontal direction; a first molding member at least partially surrounding the first semiconductor chip, the fourth semiconductor chip, and a first surface of the first redistribution structure; a conductive pillar passing through the first molding member in a vertical direction; a second redistribution structure disposed on the first molding member and including a second redistribution pattern and a second redistribution insulating layer at least partially surrounding the second redistribution pattern; a second semiconductor chip disposed on the second redistribution structure; a third semiconductor chip disposed on the second redistribution structure and spaced apart from the second semiconductor chip in the horizontal direction; and a second molding member at least partially surrounding the second semiconductor chip, the third semiconductor chip, and a first surface of the second redistribution structure, wherein a distance from the first surface of the first redistribution structure to a first surface of the first molding member is about 50 mm to about 200 mm, a distance from the first surface of the second redistribution structure to a first surface of the second molding member is about 50 mm to about 200 mm, each of the first molding member and the second molding member includes an epoxy molding compound, and each of the first redistribution insulating layer and the second redistribution insulating layer includes at least one of a photo-imageable dielectric (PID) or a photosensitive polyimide.

### BRIEF DESCRIPTION OF THE DRAWINGS

The above and other aspects of the present inventive concept will become more apparent by describing in detail embodiments thereof, with reference to the accompanying drawings, in which:

FIG. 1 is a cross-sectional view of a semiconductor package according to an embodiment of the present inventive concept;

FIG. 2 is a cross-sectional view of a semiconductor package according to an embodiment of the present inventive concept;

FIG. 3 is a cross-sectional view of a semiconductor package according to an embodiment of the present inventive concept;

FIG. 4 is a cross-sectional view of a semiconductor package according to an embodiment of the present inventive concept;

FIG. 5 is a cross-sectional view of a semiconductor package according to an embodiment of the present inventive concept;

FIG. 6 is a cross-sectional view of a semiconductor package according to an embodiment of the present inventive concept;

FIG. 7 is a cross-sectional view of a semiconductor package according to an embodiment of the present inventive concept; and

FIGS. 8A, 8B, 8C, 8D, 8E, 8F, 8G, and 8H are cross-sectional views illustrating steps of a method of manufacturing a semiconductor package, according to an embodiment of the present inventive concept.

### DETAILED DESCRIPTION OF THE EMBODIMENTS

Hereinafter, embodiments of the present inventive concept will be described with reference to the attached drawings. In the drawings, like numerals denote like elements and redundant descriptions thereof will be omitted or briefly discussed.

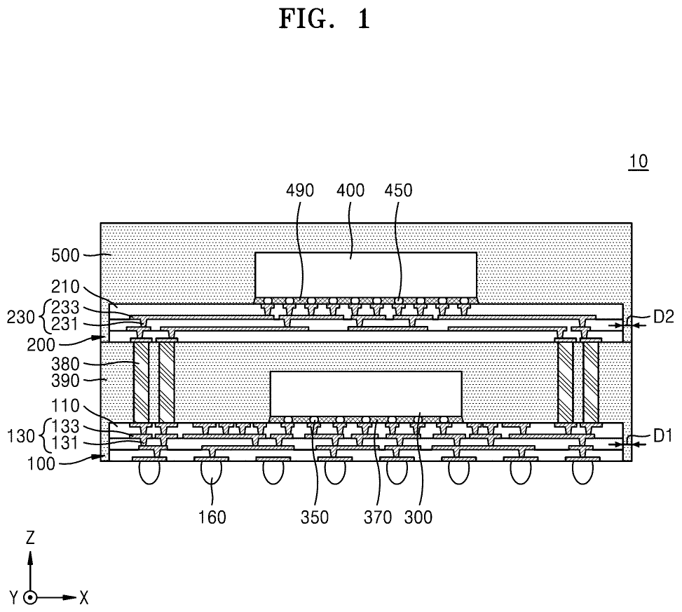

FIG. 1 is a cross-sectional view of a semiconductor package 10 according to an embodiment of the present inventive concept.

Referring to FIG. 1, the semiconductor package 10 may include a first redistribution structure 100, a first semiconductor chip 300, a first molding member 390, a conductive pillar 380, a second redistribution structure 200, a second semiconductor chip 400, and a second molding member 500.

The first redistribution structure 100 may include a top surface and a bottom surface opposite to the top surface. At least one of the top and bottom surfaces of the first redistribution structure 100 may be substantially flat. The first redistribution structure 100 may be below the first semiconductor chip 300 and may electrically connect the first semiconductor chip 300 to an external connection bump 160. The first redistribution structure 100 may include a first redistribution insulating layer 110 and a first redistribution pattern 130.

There may be a plurality of first redistribution insulating layers 110 stacked on each other in one direction (e.g., a vertical direction). The first redistribution pattern 130 may include a plurality of patterns formed in the stacked first redistribution insulating layers 110.

In the drawings, a direction in which the first redistribution insulating layers 110 are stacked may be considered as the Z-axis direction, and the X-axis direction and the Y-axis direction may be considered as being substantially perpendicular to each other on a plane that has the Z-axis direction as a normal vector. In other words, the X-axis direction and the Y-axis direction may be parallel with the top or bottom surface of the first redistribution structure 100 and may be substantially perpendicular to each other. The Z-axis direction may be orthogonal to the top or bottom surface of the first redistribution structure 100, i.e., orthogonal to an X-Y plane. Hereinafter, a first horizontal direction, a second horizontal direction, and a vertical direction in the drawings may be considered as follows. The first horizontal direction may be considered as the X-axis direction. The second horizontal direction may be considered as the Y-axis direction, and the vertical direction may be considered as the Z-axis direction.

The first redistribution pattern 130 may be electrically connected to the conductive pillar 380 and the first semiconductor chip 300. The first redistribution pattern 130 may include a first redistribution via 131 and a first redistribution line pattern 133. The first redistribution line pattern 133 may extend in the first horizontal direction X in the first redistribution insulating layer 110. According to embodiments of the present inventive concept, the first redistribution line pattern 133 may be provided in each of the plurality of first redistribution insulating layers 110 that are stacked in the vertical direction Z. The first redistribution via 131 may extend in the vertical direction Z and pass through the first redistribution insulating layer 110 in the vertical direction Z. The first redistribution via 131 may electrically connect first redistribution line patterns 133 to each other, which are respectively formed in first redistribution insulating layers 110 respectively formed at different levels.

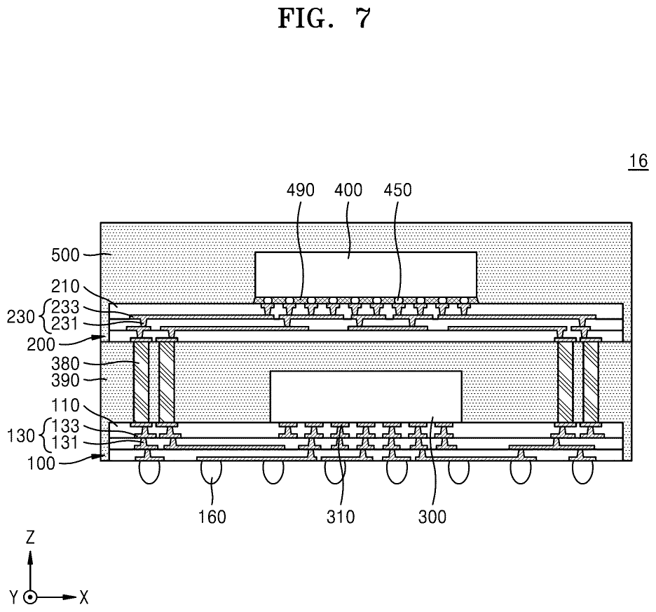

In some embodiments of the present inventive concept, the first redistribution via 131 may have a tapered shape having a horizontal width increasing upwards. For example, the horizontal width of the first redistribution via 131 may increase toward the first semiconductor chip 300. When the first redistribution via 131 has a tapered shape having a horizontal width increasing upwards, the semiconductor package 10 may be considered as being manufactured by using a chip-last process. However, embodiments of the present inventive concept are not limited thereto. As described below with reference to FIG. 7, the first redistribution via 131 may have a tapered shape having a horizontal width increasing downwards in the vertical direction Z.

The first redistribution structure 100 may be manufactured through a redistribution process. At this time, the first redistribution insulating layer 110 may be formed from, for example, a photo-imageable dielectric (PID) or photosensitive polyimide (PSPI). For example, the first redistribution pattern 130 may include, but is not limited to, metal, such as copper (Cu), aluminum (Al), tungsten (W), titanium (Ti), tantalum (Ta), indium (In), molybdenum (Mo), manganese (Mn), cobalt (Co), tin (Sn), nickel (Ni), magnesium (Mg), rhenium (Re), beryllium (Bc), gallium (Ga), or ruthenium (Ru), or an alloy thereof. In some embodiments of the present inventive concept, the first redistribution pattern 130 may be formed by stacking a metal or a metal alloy on a seed layer including copper, titanium, titanium nitride, or titanium tungsten. According to embodiments of the present inventive concept, the first redistribution line pattern 133 may be formed together with the first redistribution via 131 and thus integrated with the first redistribution via 131.

The external connection bump 160 may be disposed below the first redistribution structure 100. The external connection bump 160 may be electrically connected to an external device, e.g., a motherboard or printed circuit board. The external connection bump 160 may be electrically connected to the first redistribution pattern 130. The external connection bump 160 may transmit, to an external device, electrical signals received from the first semiconductor chip 300 and the second semiconductor chip 400 through the first redistribution pattern 130. The first redistribution pattern 130 may be electrically connected to the external device through the external connection bump 160. The external connection bump 160 may include at least one of, for example, solder, tin (Sn), silver (Ag), copper (Cu), and/or aluminum (Al).

According to embodiments of the present inventive concept, there may be a plurality of external connection bumps 160. At least one of the external connection bumps 160 might not overlap the first semiconductor chip 300 in the vertical direction Z. The area of a figure formed of virtual lines connecting outermost external connection bumps 160 among the plurality of external connection bumps 160 on the X-Y plane may be larger than the cross-sectional area of the first semiconductor chip 300 along the X-Y plane. The semiconductor package 10 having such a form may be considered as a fan-out wafer-level package.

The first semiconductor chip 300 may be mounted on the top surface of the first redistribution structure 100. The first semiconductor chip 300 may be electrically connected to the first redistribution pattern 130. According to embodiments of the present inventive concept, the first semiconductor chip 300 may be mounted on the first redistribution structure 100 in a flip chip manner. When the first semiconductor chip 300 is mounted on the first redistribution structure 100 in a flip chip manner, the first semiconductor chip 300 may be mounted on the first redistribution structure 100 through a first bump 350. According to embodiments of the present inventive concept, an underfill material layer 370 may be disposed between the first semiconductor chip 300 and the first redistribution structure 100. For example, the underfill material layer 370 may include epoxy resin formed using a capillary underfill process. However, in some embodiments of the present inventive concept, the first molding member 390 may directly fill between the first semiconductor chip 300 and the first redistribution structure 100 through a molded underfill process. In this case, the underfill material layer 370 may be omitted. However, embodiments of the present inventive concept are not limited thereto. The first semiconductor chip 300 may be mounted on the first redistribution structure 100 through wire bonding.

The first semiconductor chip 300 may include a memory chip or a logic chip. The memory chip may include, for example, a volatile memory chip, such as dynamic random access memory (DRAM) or static RAM (SRAM), or a non-volatile memory chip, such as phase-change RAM (PRAM), magnetoresistive RAM (MRAM), ferroelectric RAM (FeRAM), or resistive RAM (RRAM). For example, the logic chip may include a microprocessor such as a central processing unit (CPU), a graphics processing unit (GPU), or an application processor, an analog device, or a digital signal processor.

The first molding member 390 may be formed to at least partially surround the first semiconductor chip 300 and a side surface of the first redistribution structure 100. The side surface of the first redistribution structure 100 may be at least partially surrounded by the first molding member 390. In other words, the side surface of the first redistribution structure 100 might not be exposed to the outside due to the first molding member 390. The first redistribution insulating layer 110 may be in a side portion of the first redistribution structure 100. For example, the first redistribution insulating layer 110 may form a side surface or a portion of a side surface of the first redistribution structure 100. For example, the first redistribution pattern 130 might not be in contact with the first molding member 390 due to the first redistribution insulating layer 110. In other words, the first redistribution pattern 130 might not be exposed by the side surface of the first redistribution structure 100.

A side surface in the first horizontal direction X of the first redistribution structure 100 may overlap a side surface in the first horizontal direction X of the first molding member 390 in the first horizontal direction X. A side surface in the second horizontal direction Y of the first redistribution structure 100 may overlap a side surface in the second horizontal direction Y of the first molding member 390 in the second horizontal direction Y. The footprint of the first molding member 390 may be greater than the footprint of the first redistribution structure 100.

According to embodiments of the present inventive concept, a minimum distance D1 from a side surface of the first redistribution structure 100 to a side surface of the first molding member 390 may be about 50 μm to about 200 μm. In other words, a length of a portion of the first molding member 390 surrounding the side surface of the first redistribution structure 100 may be about 50 μm to about 200 μm in the first horizontal direction X.

The first molding member 390 may include a material having low moisture absorption. In other words, the first molding member 390 may include a material that blocks moisture. The first molding member 390 may include a material having a low coefficient of thermal expansion. The first molding member 390 may be formed from thermosetting resin such as epoxy resin, thermoplastic resin such as polyimide, or resin, such as an Ajinomoto build-up film (ABF), flame retardant 4 (FR-4), or bismaleimide triazine (BT), which includes a reinforcing agent, such as an inorganic filler, in thermosetting resin or thermoplastic resin, but the present inventive concept is not limited thereto. The first molding member 390 may be formed from a molding material, e.g., an epoxy mold compound (EMC), or a photosensitive material, e.g., a photo-imageable encapsulant. In some embodiments of the present inventive concept, a portion of the first molding member 390 may include an insulating material, such as a silicon oxide film, a silicon nitride film, or a silicon oxynitride film.

The conductive pillar 380 may be disposed on the top surface of the first redistribution structure 100 and may be separated from the first semiconductor chip 300 in a horizontal direction. According to embodiments of the present inventive concept, there may be a plurality of conductive pillars 380. The conductive pillars 380 may be spaced apart from each other by a certain distance in a horizontal direction. The conductive pillar 380 may extend in the vertical direction Z and pass through the first molding member 390 in the vertical direction Z.

The conductive pillar 380 may electrically connect the second redistribution structure 200 to the first redistribution structure 100. In other words, the conductive pillar 380 may correspond to a vertical connection conductor for electrically connecting the first redistribution structure 100 to the second redistribution structure 200.

The top surface of the conductive pillar 380 may be substantially coplanar with the top surface of the first molding member 390. In embodiments of the present inventive concept, the top surface of the first semiconductor chip 300 may be lower than the top surface of the first molding member 390 in the vertical direction Z.

The second redistribution structure 200 may be disposed on the top surface of the first molding member 390. The second redistribution structure 200 may include a top surface and a bottom surface opposite to the top surface. At least one of the top and bottom surfaces of the second redistribution structure 200 may be substantially flat. The second redistribution structure 200 may electrically connect the conductive pillar 380 to the second semiconductor chip 400. The second redistribution structure 200 may include a second redistribution insulating layer 210 and a second redistribution pattern 230. The second redistribution structure 200 may electrically connect the conductive pillar 380 to the second semiconductor chip 400 through the second redistribution pattern 230. There may be a plurality of second redistribution insulating layers 210 stacked in the vertical direction Z. The second redistribution pattern 230 may include a second redistribution via 231 and a second redistribution line pattern 233.

The second redistribution pattern 230 and the second redistribution insulating layer 210 may be substantially the same as or similar to the first redistribution pattern 130 and the first redistribution insulating layer 110, respectively, and thus, redundant descriptions thereof may be omitted or briefly described.

The second semiconductor chip 400 may be mounted on the top surface of the second redistribution structure 200. The second semiconductor chip 400 may be mounted on the top surface of the second redistribution structure 200 in a flip chip manner through a second bump 450.

The second semiconductor chip 400 may include a memory chip or a logic chip. According to embodiments of the present inventive concept, an underfill material layer 490 surrounding the second bump 450 may be between the second semiconductor chip 400 and the second redistribution structure 200. For example, the underfill material layer 490 may include epoxy resin formed using a capillary underfill process. However, in some embodiments of the present inventive concept, a molding material may directly fill between the second semiconductor chip 400 and the second redistribution structure 200 through a molded underfill process. In this case, the underfill material layer 490 may be omitted. The second bump 450 may be disposed between the second semiconductor chip 400 and the second redistribution structure 200. There may be a plurality of second bumps 450.

The second molding member 500 may surround the second semiconductor chip 400 and a side surface of the second redistribution structure 200. The side surface of the second redistribution structure 200 may be at least partially surrounded by the second molding member 500. In other words, the side surface of the second redistribution structure 200 might not be exposed to the outside due to the second molding member 500. The second redistribution insulating layer 210 may be in a side portion of the second redistribution structure 200. For example, a side surface of the second redistribution insulating layer 210 may be a side surface or a portion of a side surface of the second redistribution structure 200. That is, the second redistribution pattern 230 might not be in contact with the second molding member 500 due to the second redistribution insulating layer 210. In other words, the second redistribution pattern 230 might not be exposed by the side surface of the second redistribution structure 200.

A side surface in the first horizontal direction X of the second redistribution structure 200 may overlap a side surface in the first horizontal direction X of the second molding member 500 in the first horizontal direction X. A side surface in the second horizontal direction Y of the second redistribution structure 200 may overlap a side surface in the second horizontal direction Y of the second molding member 500 in the second horizontal direction Y. The footprint of the second molding member 500 may be greater than the footprint of the second redistribution structure 200. For example, the second molding member 500 may have a surface area that is larger than that of the second redistribution structure 200. For example, the second molding member 500 may cover the second redistribution structure 200.

According to embodiments of the present inventive concept, a minimum distance D2 from a side surface of the second redistribution structure 200 to a side surface of the second molding member 500 may be about 50 μm to about 200 μm. In other words, a length of a portion of the second molding member 500 surrounding the side surface of the second redistribution structure 200 may be about 50 μm to about 200 μm in the first horizontal direction X.

The minimum distance D1 from the side surface of the first redistribution structure 100 to the side surface of the first molding member 390 may be the same or substantially the same as the minimum distance D2 from the side surface of the second redistribution structure 200 to the side surface of the second molding member 500, but embodiments of the present inventive concept are not limited thereto. For example, the minimum distance D1 may be different from the minimum distance D2.

The material of the second molding member 500 may be substantially the same as or similar to that of the first molding member 390, and thus, descriptions thereof are omitted.

According to an embodiment of the present inventive concept, the semiconductor package 10 may include the first molding member 390, which covers the side surface of the first redistribution structure 100, and the second molding member 500, which covers the side surface of the second redistribution structure 200, such that the first redistribution insulating layer 110 and the second redistribution insulating layer 210 may be sealed from the outside. Each of the first redistribution insulating layer 110 and the second redistribution insulating layer 210 may include a PID and a pure polymer and thus have a high moisture absorption. In the case in which the first redistribution insulating layer 110 and the second redistribution insulating layer 210, each having a high moisture absorption, are exposed to the outside, moisture may penetrate the first redistribution insulating layer 110 and the second redistribution insulating layer 210 so that the first redistribution insulating layer 110 and the second redistribution insulating layer 210 may swell or bend.

However, in the semiconductor package 10 according to an embodiment of the present inventive concept, the first molding member 390 and the second molding member 500 may respectively surround the first redistribution structure 100 and the second redistribution structure 200 such that the first redistribution insulating layer 110 and the second redistribution insulating layer 210 are sealed from the outside, and accordingly, moisture may be prevented from penetrating into the first redistribution insulating layer 110 and the second redistribution insulating layer 210. Because the material of each of the first molding member 390 and the second molding member 500 has low moisture absorption, moisture may be prevented from penetrating the first redistribution insulating layer 110 and the second redistribution insulating layer 210 respectively through the first molding member 390 and the second molding member 500.

Moreover, a certain space may be present to allow the first molding member 390 and the second molding member 500 to respectively surround the respective side surfaces of the first redistribution structure 100 and the second redistribution structure 200, and accordingly, the length of each of the first redistribution structure 100 and the second redistribution structure 200 in a horizontal direction may be reduced compared to semiconductor packages according to the related art. Because the length of each of the first redistribution structure 100 and the second redistribution structure 200 is reduced compared to semiconductor packages according to the related art, warpage of the semiconductor package 10 may also be reduced.

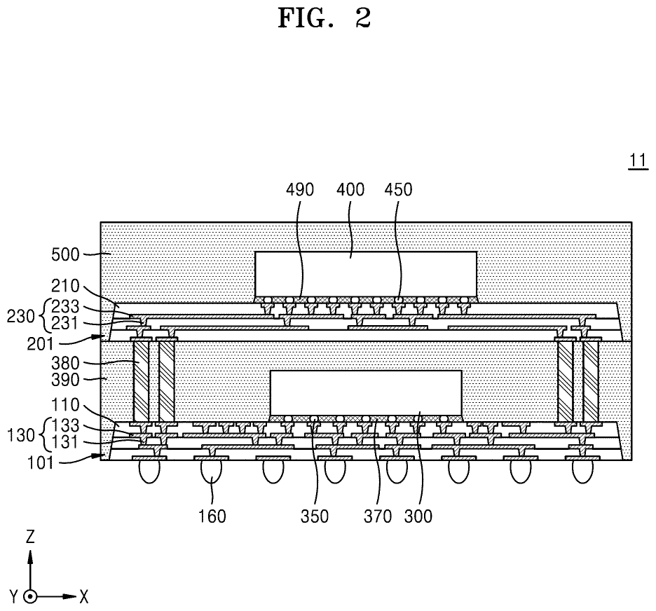

FIG. 2 is a cross-sectional view of a semiconductor package 11 according to an embodiment of the present inventive concept. Redundant descriptions of the semiconductor package 10 of FIG. 1 are omitted and differences between the semiconductor package 11 of FIG. 2 and the semiconductor package 10 of FIG. 1 are mainly described below.

Referring to FIG. 2, the semiconductor package 11 may include a first redistribution structure 101, the first semiconductor chip 300, the first molding member 390, the conductive pillar 380, a second redistribution structure 201, the second semiconductor chip 400, and the second molding member 500.

The first redistribution structure 101 may include the first redistribution insulating layer 110 and the first redistribution pattern 130. There may be a plurality of first redistribution insulating layers 110 stacked on each other in one direction. The first redistribution pattern 130 may include a plurality of patterns formed in the stacked first redistribution insulating layers 110.

The first redistribution structure 101 may have a tapered shape having a horizontal width increasing downwards in the vertical direction Z. In other words, a side surface of the first redistribution structure 101 may form an obtuse angle with respect to the bottom surface of the first molding member 390. The side surface of the first redistribution structure 101 may be formed by an exposure process and an etching process such that the horizontal width of the first redistribution structure 101 increases downwards in the vertical direction Z. In addition, a portion of the first molding member 390, which covers the side surface of the first redistribution structure 101, may have a shape having a horizontal width decreasing downwards in the vertical direction Z.

The second redistribution structure 201 may have a tapered shape having a horizontal width increasing downwards in the vertical direction Z. In other words, a side surface of the second redistribution structure 201 may form an obtuse angle with respect to the bottom surface of the second molding member 500. The side surface of the second redistribution structure 201 may be formed by an exposure process and an etching process such that the horizontal width of the second redistribution structure 201 increases downwards in the vertical direction Z. In addition, a portion of the second molding member 500 covering the side surface of the second redistribution structure 201 may have a shape having a horizontal width decreasing downwards in the vertical direction Z.

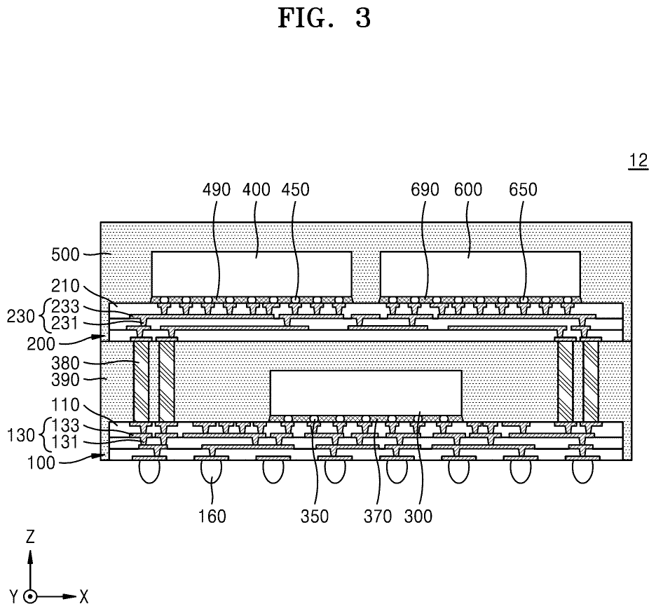

FIG. 3 is a cross-sectional view of a semiconductor package 12 according to an embodiment of the present inventive concept. Redundant descriptions of the semiconductor package 10 of FIG. 1 are omitted and differences between the semiconductor package 12 of FIG. 3 and the semiconductor package 10 of FIG. 1 are mainly described below.

Referring to FIG. 3, the semiconductor package 12 may include the first redistribution structure 100, the first semiconductor chip 300, the first molding member 390, the conductive pillar 380, the second redistribution structure 200, the second semiconductor chip 400, a third semiconductor chip 600, and the second molding member 500.

The second semiconductor chip 400 and the third semiconductor chip 600 may be mounted on the second redistribution structure 200. The second semiconductor chip 400 and the third semiconductor chip 600 may be spaced apart from each other in the first horizontal direction X. The third semiconductor chip 600 may include a memory chip or a logic chip.

The second redistribution structure 200 may electrically connect each of the second semiconductor chip 400 and the third semiconductor chip 600 to the conductive pillar 380. For example, the second semiconductor chip 400 may be electrically connected to the conductive pillar 380 through the second redistribution pattern 230, and the third semiconductor chip 600 may be electrically connected to the conductive pillar 380 through the second redistribution pattern 230.

According to embodiments of the present inventive concept, the third semiconductor chip 600 may be mounted on the second redistribution structure 200 in a flip chip manner. The third semiconductor chip 600 may be mounted on the second redistribution structure 200 through a third bump 650 in a flip chip manner. According to embodiments of the present inventive concept, an underfill material layer 690 may be disposed between the third semiconductor chip 600 and the second redistribution structure 200. For example, the underfill material layer 690 may include epoxy resin formed using a capillary underfill process. However, in some embodiments of the present inventive concept, the second molding member 500 may directly fill between the third semiconductor chip 600 and the second redistribution structure 200 through a molded underfill process. In this case, the underfill material layer 690 may be omitted. However, embodiments of the present inventive concept are not limited thereto. The third semiconductor chip 600 may be mounted on the second redistribution structure 200 through wire bonding.

According to an embodiment of the present inventive concept, the first semiconductor chip 300 may be mounted on the top surface of the first redistribution structure 100, and the second semiconductor chip 400 and the third semiconductor chip 600 may be mounted on the top surface of the second redistribution structure 200, such that the semiconductor package 12 may have a structure including a total of three semiconductor chips.

According to embodiments of the present inventive concept, the second semiconductor chip 400 may be of the same type as the third semiconductor chip 600. For example, each of the second semiconductor chip 400 and the third semiconductor chip 600 may be a memory chip. However, embodiments of the present inventive concept are not limited thereto. The second semiconductor chip 400 may be of a different type than that of the third semiconductor chip 600. For example, when the second semiconductor chip 400 is a memory chip, the third semiconductor chip 600 may be a logic chip. When the second semiconductor chip 400 is of a different type than that of the third semiconductor chip 600, an interposer substrate may be further provided to electrically connect the second semiconductor chip 400 to the third semiconductor chip 600.

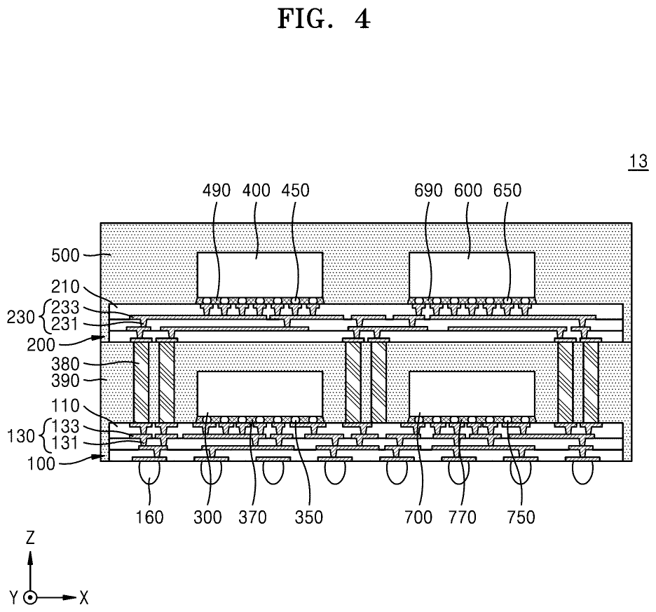

FIG. 4 is a cross-sectional view of a semiconductor package 13 according to an embodiment of the present inventive concept. Redundant descriptions of the semiconductor package 12 of FIG. 3 are omitted and differences between the semiconductor package 13 of FIG. 4 and the semiconductor package 12 of FIG. 3 are mainly described below.

Referring to FIG. 4, the semiconductor package 13 may include the first redistribution structure 100, the first semiconductor chip 300, a fourth semiconductor chip 700, the first molding member 390, the conductive pillar 380, the second redistribution structure 200, the second semiconductor chip 400, the third semiconductor chip 600, and the second molding member 500.

The first semiconductor chip 300 and the fourth semiconductor chip 700 may be mounted on the first redistribution structure 100. The first semiconductor chip 300 and the fourth semiconductor chip 700 may be spaced apart from each other in the first horizontal direction X. The fourth semiconductor chip 700 may include a memory chip or a logic chip.

The first redistribution structure 100 may be electrically connected to the first semiconductor chip 300 and the fourth semiconductor chip 700. For example, each of the first semiconductor chip 300 and the fourth semiconductor chip 700 may be electrically connected to the first redistribution pattern 130.

According to embodiments of the present inventive concept, the fourth semiconductor chip 700 may be mounted on the first redistribution structure 100 in a flip chip manner. The fourth semiconductor chip 700 may be mounted on the first redistribution structure 100 through a fourth bump 750 in a flip chip manner.

According to embodiments of the present inventive concept, an underfill material layer 770 may be disposed between the fourth semiconductor chip 700 and the first redistribution structure 100. For example, the underfill material layer 770 may include epoxy resin formed using a capillary underfill process. However, in some embodiments of the present inventive concept, the first molding member 390 may directly fill between the fourth semiconductor chip 700 and the first redistribution structure 100 through a molded underfill process. In this case, the underfill material layer 770 may be omitted. However, embodiments of the present inventive concept are not limited thereto. The fourth semiconductor chip 700 may be mounted on the first redistribution structure 100 through wire bonding. A conductive pillar 380 may be disposed between the first semiconductor chip 300 and the fourth semiconductor chip 700. In other words, the first semiconductor chip 300 and the fourth semiconductor chip 700 may be spaced apart from each other in the first horizontal direction X with the conductive pillar 380 therebetween.

The second semiconductor chip 400 and the third semiconductor chip 600 may be mounted on the top surface of the second redistribution structure 200 and may be spaced apart from each other in the first horizontal direction X. In addition, according to an embodiment of the present inventive concept, the first semiconductor chip 300 and the fourth semiconductor chip 700 may be mounted on the first redistribution structure 100, and the second semiconductor chip 400 and the third semiconductor chip 600 may be mounted on the second redistribution structure 200, such that the semiconductor package 13 may have a structure including a total of four semiconductor chips.

According to embodiments of the present inventive concept, the first semiconductor chip 300 may be of the same type as that of the fourth semiconductor chip 700. For example, each of the first semiconductor chip 300 and the fourth semiconductor chip 700 may be a memory chip. However, embodiments of the present inventive concept are not limited thereto. The first semiconductor chip 300 may be of a different type than that of the fourth semiconductor chip 700. For example, when the first semiconductor chip 300 is a memory chip, the fourth semiconductor chip 700 may be a logic chip.

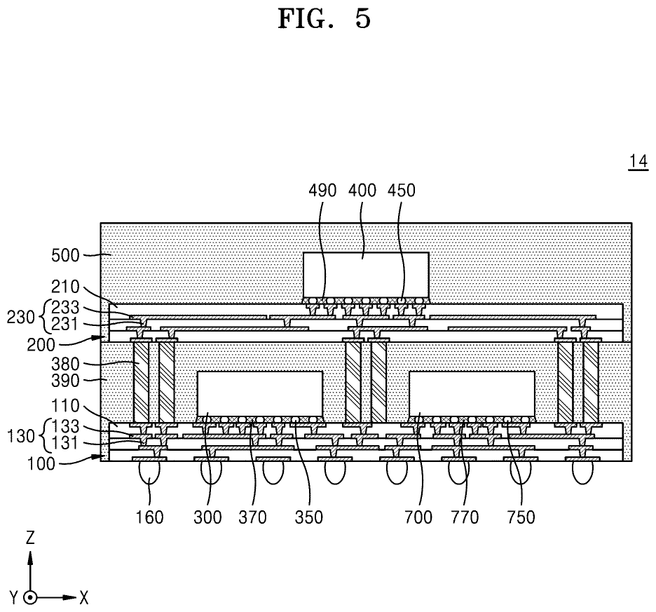

FIG. 5 is a cross-sectional view of a semiconductor package 14 according to an embodiment of the present inventive concept. Redundant descriptions of the semiconductor package 13 of FIG. 4 are omitted and differences between the semiconductor package 14 of FIG. 5 and the semiconductor package 13 of FIG. 4 are mainly described below.

Referring to FIG. 5, the semiconductor package 14 may include the first redistribution structure 100, the first semiconductor chip 300, the fourth semiconductor chip 700, the first molding member 390, the conductive pillar 380, the second redistribution structure 200, the second semiconductor chip 400, and the second molding member 500.

The first semiconductor chip 300 and the fourth semiconductor chip 700 may be mounted on the first redistribution structure 100. The first semiconductor chip 300 and the fourth semiconductor chip 700 may be spaced apart from each other in the first horizontal direction X. The conductive pillar 380 may be disposed between the first semiconductor chip 300 and the fourth semiconductor chip 700. The second semiconductor chip 400 may be mounted on the second redistribution structure 200. For example, each of the first semiconductor chip 300, the second semiconductor chip 400, and the fourth semiconductor chip 700 may include a memory chip or a logic chip. According to embodiments of the present inventive concept, the first semiconductor chip 300, the second semiconductor chip 400, and the fourth semiconductor chip 700 may be of the same type as one another, or two semiconductor chips among the first semiconductor chip 300, the second semiconductor chip 400, and the fourth semiconductor chip 700 may be of the same type as each other and may be of a different type than the other semiconductor chip.

In addition, according to an embodiment of the present inventive concept, the first semiconductor chip 300 and the fourth semiconductor chip 700 may be mounted on the first redistribution structure 100, and the second semiconductor chip 400 may be mounted on the second redistribution structure 200, such that the semiconductor package 14 may have a structure including a total of three semiconductor chips.

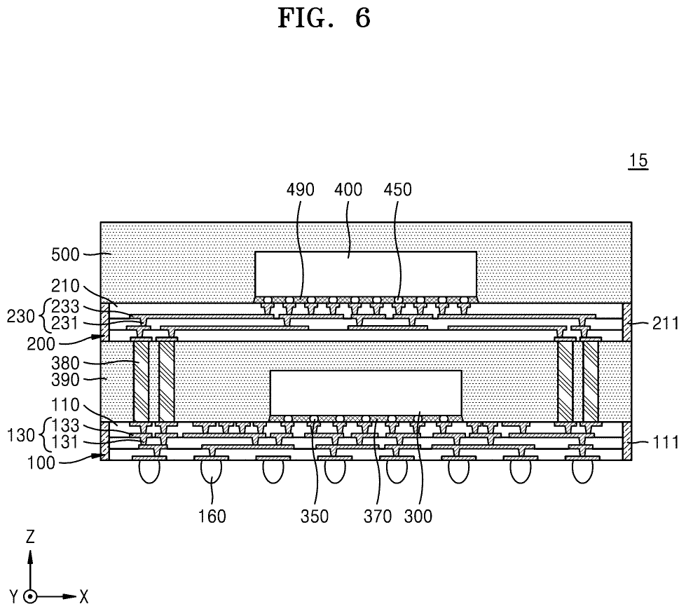

FIG. 6 is a cross-sectional view of a semiconductor package 15 according to an embodiment of the present inventive concept. Redundant descriptions of the semiconductor package 10 of FIG. 1 are omitted and differences between the semiconductor package 15 of FIG. 6 and the semiconductor package 10 of FIG. 1 are mainly described below.

Referring to FIG. 6, the semiconductor package 15 may include the first redistribution structure 100, the first semiconductor chip 300, the first molding member 390, a first cover 111, the conductive pillar 380, the second redistribution structure 200, the second semiconductor chip 400, a second cover 211, and the second molding member 500.

The first cover 111 may cover a side surface of the first redistribution structure 100. The first cover 111 may at least partially surround the side surface of the first redistribution structure 100. According to embodiments of the present inventive concept, the first cover 111 may include copper. The first cover 111 may be formed by copper plating. However, embodiments of the present inventive concept are not limited thereto. The first cover 111 may include a material, which is different from the material of the first molding member 390 and has low moisture absorption.

The first molding member 390 may cover the top surface of the first cover 111 and the top surface of the first redistribution structure 100. The bottom surface of the first molding member 390 may be substantially coplanar with the top surface of the first cover 111 and the top surface of the first redistribution structure 100. According to embodiments of the present inventive concept, the footprint of the first molding member 390 may be greater than the footprint of the first redistribution structure 100.

The second cover 211 may cover a side surface of the second redistribution structure 200. The second cover 211 may at least partially surround the side surface of the second redistribution structure 200. According to embodiments of the present inventive concept, the second cover 211 may include copper. The second cover 211 may be formed by copper plating. However, embodiments of the present inventive concept are not limited thereto. The second cover 211 may include a material, which is different from the material of the second molding member 500 and has low moisture absorption.

According to embodiments of the present inventive concept, the footprint of the second molding member 500 may be greater than the footprint of the second redistribution structure 200.

FIG. 7 is a cross-sectional view of a semiconductor package 16 according to an embodiment of the present inventive concept. Redundant descriptions of the semiconductor package 10 of FIG. 1 are omitted and differences between the semiconductor package 16 of FIG. 7 and the semiconductor package 10 of FIG. 1 are mainly described below.

Referring to FIG. 7, the semiconductor package 16 may include the first redistribution structure 100, the first semiconductor chip 300, the first molding member 390, the conductive pillar 380, the second redistribution structure 200, the second semiconductor chip 400, and the second molding member 500.

The first redistribution pattern 130 may include the first redistribution via 131 and the first redistribution line pattern 133. According to embodiments of the present inventive concept, the first redistribution via 131 may have a tapered shape having a horizontal width increasing downwards in the vertical direction Z. The first semiconductor chip 300 may include a first semiconductor chip pad 310. The first semiconductor chip 300 may be mounted on the first redistribution structure 100 and electrically connected to the first redistribution structure 100 without a separate bump like a solder ball. The first semiconductor chip pad 310 may be directly connected to the first redistribution pattern 130. When the horizontal width of the first redistribution via 131 increases downwards in the vertical direction Z and the first semiconductor chip pad 310 is directly connected to the first redistribution pattern 130, it may be considered that the semiconductor package 16 is manufactured by a chip-first process.

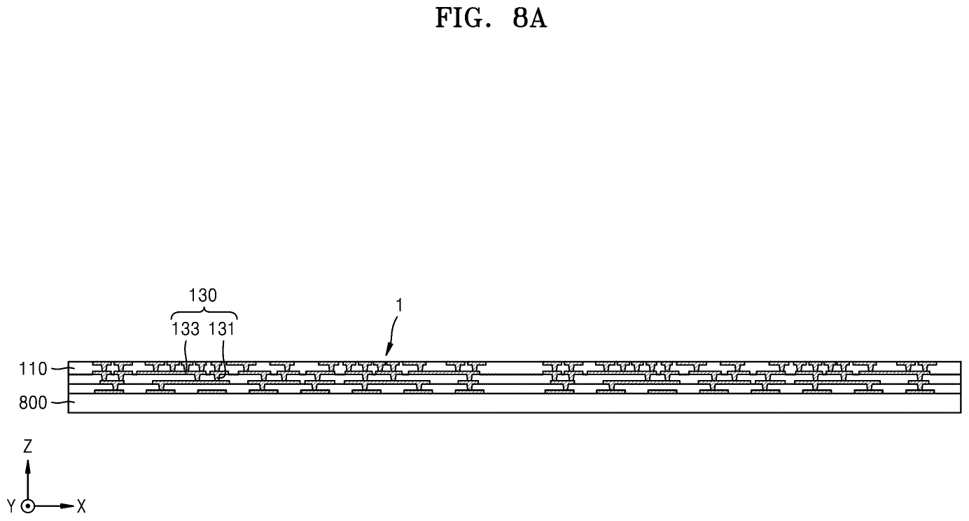

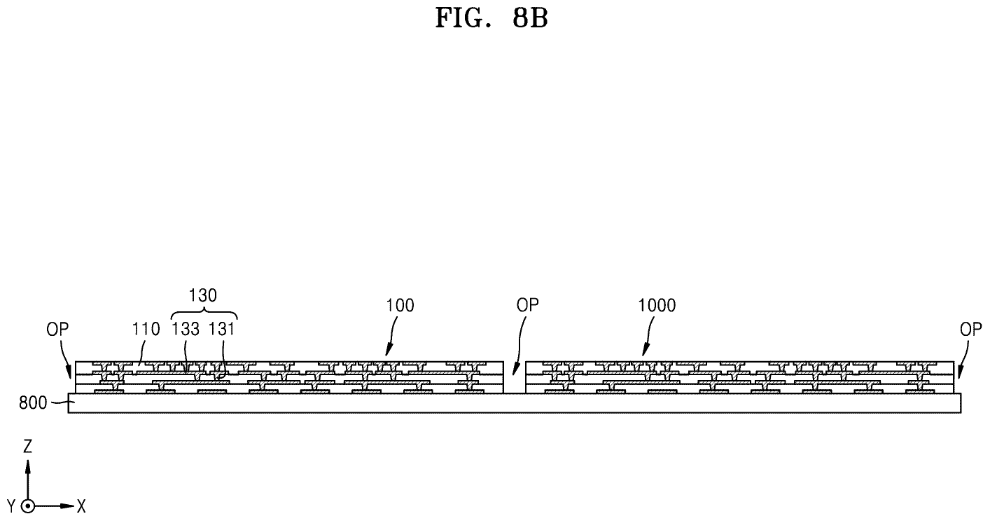

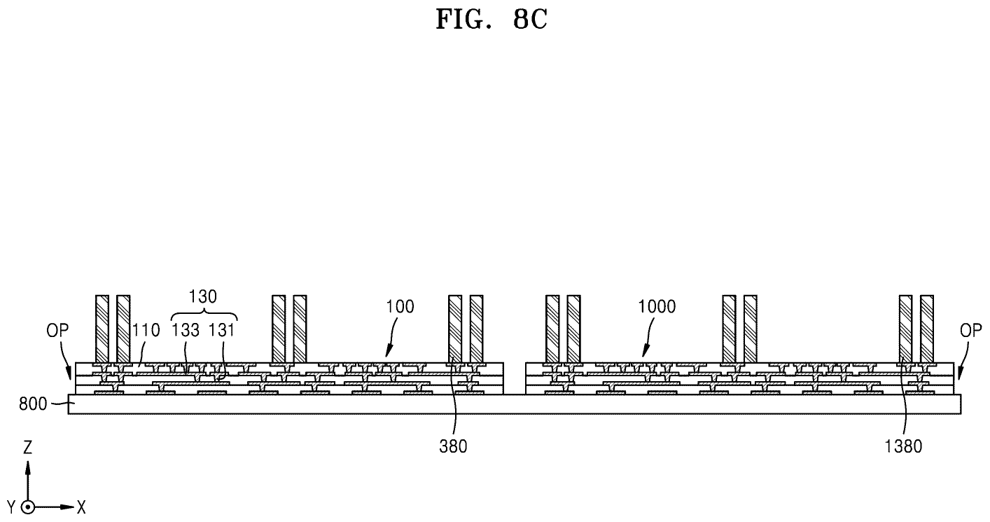

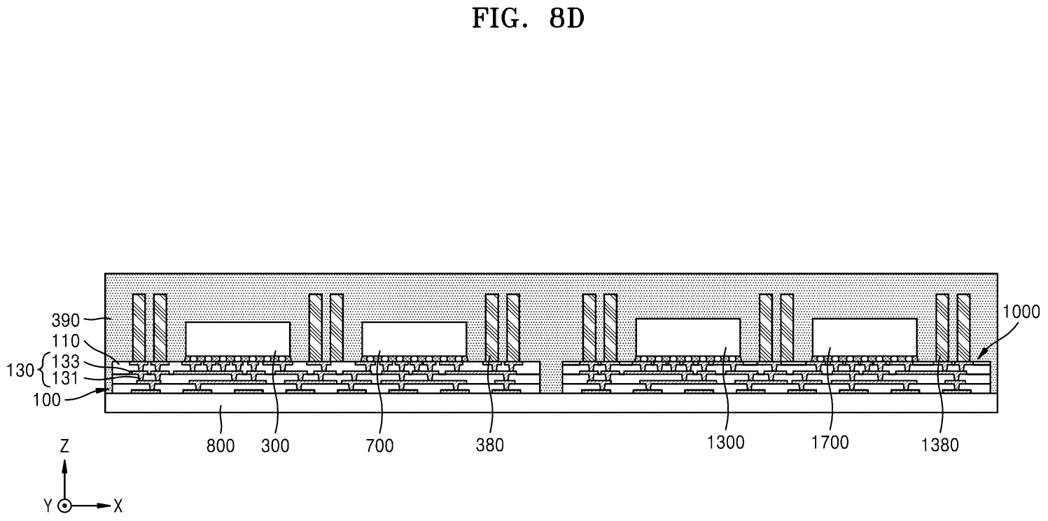

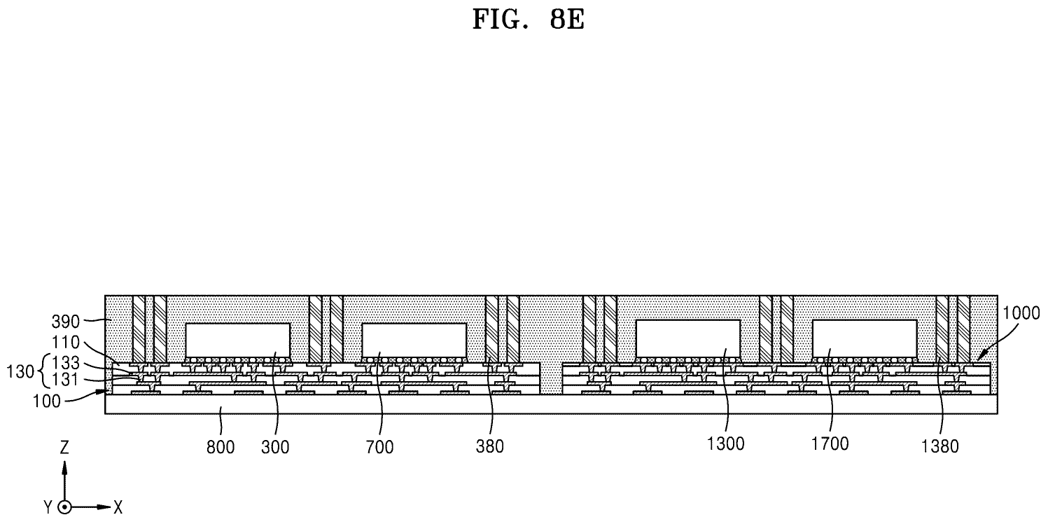

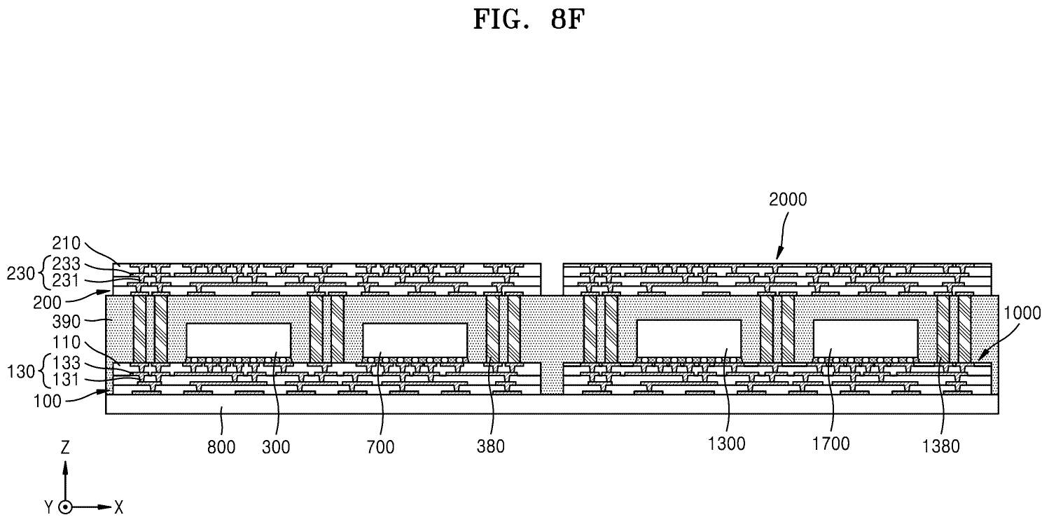

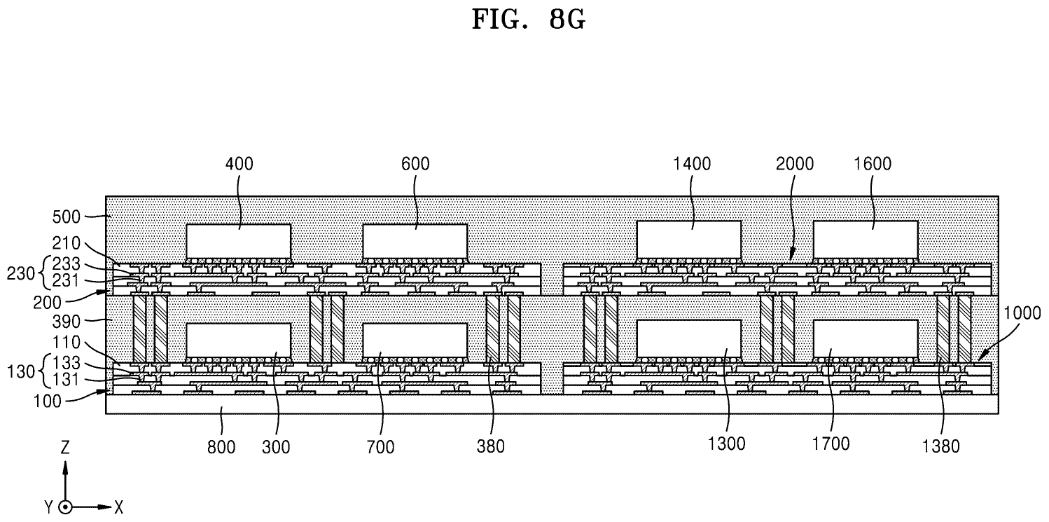

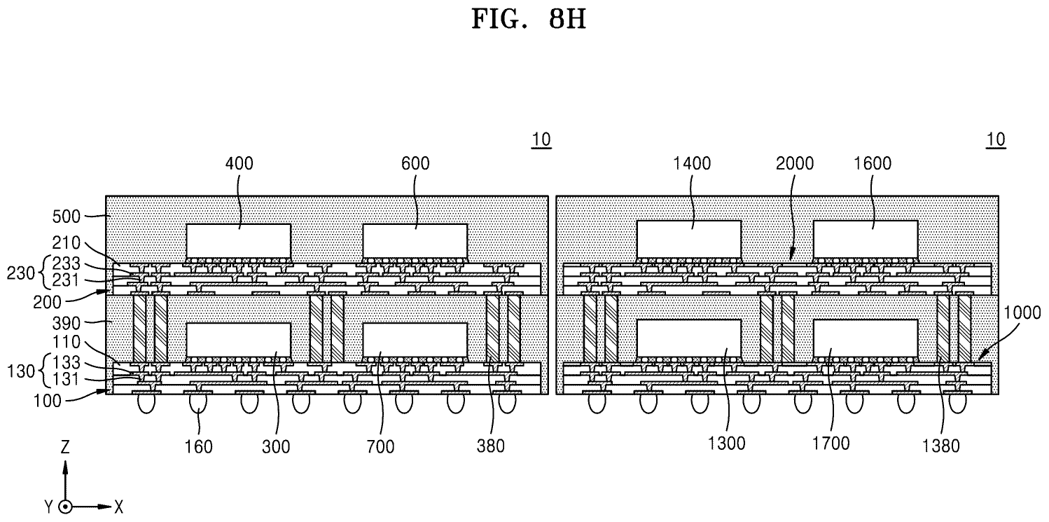

FIGS. 8A to 8H are cross-sectional views of stages in a method of manufacturing a semiconductor package, according to an embodiment of the present inventive concept. Hereinafter, the method of manufacturing a semiconductor package is described with reference to FIGS. 8A to 8H.

Referring to FIG. 8A, a first redistribution structure 1 may be formed on a carrier substrate 800. The first redistribution structure 1 is substantially the same as the first redistribution structure 100 described with reference to FIG. 1, and thus, redundant descriptions thereof are omitted. The first redistribution structure 1 may be formed on the carrier substrate 800 with no gaps. In other words, the footprint of the first redistribution structure 1 may be substantially the same as the footprint of the carrier substrate 800.

Referring to FIG. 8B, after the first redistribution structure 1 is formed, an opening OP may be formed in the first redistribution structure 1 by exposure. A plurality of openings OP may be formed in the first redistribution structure 1. For example, the openings OP may be formed in opposite sides and the central portion of the carrier substrate 800. The first redistribution structure 1 may be divided into two first redistribution structures 100 and 1000 by the openings OP. The first redistribution structures 100 and 1000 are substantially the same as each other, and thus, detailed descriptions thereof are omitted.

Opposite edge portions of the carrier substrate 800 may be respectively exposed from the first redistribution structures 100 and 1000 by openings OP on the opposite sides of the carrier substrate 800. For example, the left edge portion of the top surface of the carrier substrate 800 may be exposed upwards in the vertical direction Z from the first redistribution structure 100 by an opening OP formed on the left edge portion of the top surface of the carrier substrate 800, and the right edge portion of the top surface of the carrier substrate 800 may be exposed upwards in the vertical direction Z from the first redistribution structure 1000 by an opening OP formed on the right edge portion of the top surface of the carrier substrate 800.

Referring to FIG. 8C, conductive pillars 380 and 1380 may be respectively formed on the first redistribution structures 100 and 1000. According to embodiments of the present inventive concept, the conductive pillars 380 and 1380 may be formed by filling photoresist openings, which are formed by photoresist deposition, exposure, and etching, with copper.

Referring to FIG. 8D, a first semiconductor chip 300 and a fourth semiconductor chip 700 may be mounted on the first redistribution structure 100, and a first semiconductor chip 1300 and a fourth semiconductor chip 1700 may be mounted on the first redistribution structure 1000. A first molding member 390 may be formed to at least partially surround the first semiconductor chips 300 and 1300, the fourth semiconductor chips 700 and 1700, and the conductive pillars 380 and 1380. In addition, the first molding member 390 may cover the side surfaces of the first redistribution structures 100 and 1000. In other words, the first molding member 390 may fill the openings OP described with reference to FIG. 8B. Accordingly, the top surface of the carrier substrate 800 might not be exposed upwards in the vertical direction Z.

Referring to FIG. 8E, the top surface of the first molding member 390 may be ground such that the top surface of the first molding member 390 is at substantially the same level in the vertical direction Z as the top surface of each of the conductive pillars 380 and 1380. The grinding may be carried out by a chemical mechanical polishing (CMP) process.

Referring to FIG. 8F, second redistribution structures 200 and 2000 may be formed on the top surface of the first molding member 390. The forming of the second redistribution structures 200 and 2000 may be substantially the same as or similar to the forming of the first redistribution structures 100 and 1000, and thus, detailed descriptions thereof are omitted.

Referring to FIG. 8G, a second semiconductor chip 400 and a third semiconductor chip 600 may be mounted on the second redistribution structure 200, and a second semiconductor chip 1400 and a third semiconductor chip 1600 may be mounted on the second redistribution structure 2000. In addition, a second molding member 500 may be formed to at least partially surround the second semiconductor chips 400 and 1400 and the third semiconductor chips 600 and 1600.

In addition, the second molding member 500 may at least partially surround the side surfaces of the second redistribution structures 200 and 2000. The second molding member 500 surrounding the side surfaces of the second redistribution structures 200 and 2000 may be in contact with the first molding member 390.

Referring to FIG. 8H, an external connection bump 160 may be formed on the bottom surface of each of the first redistribution structures 100 and 1000, and then, the resultant structure is singulated into semiconductor packages 10 by dicing. The dicing may be carried out by separating the first molding member 390 and the second molding member 500, and accordingly, the first redistribution structures 100 and 1000 and the second redistribution structures 200 and 2000 might not be damaged by the dicing.

While the present inventive concept has been particularly shown and described with reference to example embodiments thereof, it will be apparent to those of ordinary skill in the art that various changes in form and detail may be made thereto without departing from the spirit and scope of the present inventive concept.

What is claimed is:

1. A semiconductor package comprising:
a first redistribution structure comprising a first redistribution pattern and a first redistribution insulating layer at least partially surrounding the first redistribution pattern;
a first semiconductor chip disposed on the first redistribution structure;
a first molding member surrounding the first semiconductor chip and a side surface of the first redistribution structure;
a conductive pillar passing through the first molding member;
a second redistribution structure disposed on the first molding member and comprising a second redistribution pattern and a second redistribution insulating layer at least partially surrounding the second redistribution pattern;
a second semiconductor chip disposed on the second redistribution structure; and
a second molding member surrounding the second semiconductor chip and a side surface of the second redistribution structure.

2. The semiconductor package as claimed in claim 1, wherein
each of the first redistribution structure and the second redistribution structure has a tapered shape having a horizontal width increasing downwards in the vertical direction.

3. The semiconductor package as claimed in claim 1, further comprising
a third semiconductor chip disposed on a top surface of the second redistribution structure and apart from the second semiconductor chip in a horizontal direction.

4. The semiconductor package as claimed in claim 1, further comprising
a fourth semiconductor chip disposed on a top surface of the first redistribution structure and spaced apart from the first semiconductor chip in a horizontal direction.

5. The semiconductor package as claimed in claim 4, wherein
the conductive pillar is between the first semiconductor chip and the fourth semiconductor chip.

6. The semiconductor package as claimed in claim 1, wherein
the first redistribution pattern comprises a first redistribution via and a first redistribution line pattern, wherein the first redistribution via extends in a vertical direction, and the first redistribution line pattern extends in a horizontal direction,
a first bump and an underfill material layer are between the first redistribution structure and the first semiconductor chip, and
the first redistribution via has a tapered shape having a horizontal width decreasing downwards in a vertical direction.

7. The semiconductor package as claimed in claim 1, wherein
the first redistribution pattern comprises a first redistribution via and a first redistribution line pattern, wherein the first redistribution via extends in a vertical direction, and the first redistribution line pattern extends in a horizontal direction, and
the first redistribution via has a tapered shape having a horizontal width increasing downwards in the vertical direction.

8. The semiconductor package as claimed in claim 1, wherein
each of the first molding member and the second molding member includes an epoxy molding compound, and
each of the first redistribution insulating layer and the second redistribution insulating layer includes at least one of a photo-imageable dielectric (PID) or a photosensitive polyimide.

9. The semiconductor package as claimed in claim 1, wherein
an area of the first molding member is greater than an area of the first redistribution structure, and an area of the second molding member is greater than an of the second redistribution structure.

10. The semiconductor package as claimed in claim 1, further comprising:
a fourth semiconductor chip disposed on a top surface of the first redistribution structure and spaced apart from the first semiconductor chip in a horizontal direction; and
a third semiconductor chip disposed on a top surface of the second redistribution structure and spaced apart from the second semiconductor chip in the horizontal direction.

11. A semiconductor package comprising:
a first redistribution structure comprising a first redistribution pattern and a first redistribution insulating layer at least partially surrounding the first redistribution pattern;
a first cover surrounding a side surface of the first redistribution structure;
a first semiconductor chip disposed on the first redistribution structure;
a first molding member disposed on the first redistribution structure and at least partially surrounding the first semiconductor chip;
a conductive pillar passing through the first molding member;
a second redistribution structure disposed on the first molding member and comprising a second redistribution pattern and a second redistribution insulating layer at least partially surrounding the second redistribution pattern;
a second cover surrounding a side surface of the second redistribution structure;
a second semiconductor chip disposed on the second redistribution structure; and
a second molding member disposed on the second redistribution structure and at least partially surrounding the second semiconductor chip.

12. The semiconductor package as claimed in claim 11, wherein
each of the first cover and the second cover includes copper.

13. The semiconductor package as claimed in claim 11, further comprising:
a fourth semiconductor chip disposed on the first redistribution structure and spaced apart from the first semiconductor chip in a horizontal direction; and
a third semiconductor chip disposed on the second redistribution structure and spaced apart from the second semiconductor chip in the horizontal direction.

14. The semiconductor package as claimed in claim 11, wherein
each of the first redistribution structure and the second redistribution structure has a tapered shape.

15. The semiconductor package as claimed in claim 11, wherein
the first redistribution pattern comprises a first redistribution via and a first redistribution line pattern, wherein the first redistribution via extends in a vertical direction, and the first redistribution line pattern may extend in a horizontal direction,
a first bump and an underfill material layer are disposed between the first redistribution structure and the first semiconductor chip, and
the first redistribution via has a tapered shape having a horizontal width decreasing downwards in the vertical direction.

16. The semiconductor package as claimed in claim 11, wherein
the first redistribution pattern comprises a first redistribution via and a first redistribution line pattern, wherein the first redistribution via extends in a vertical direction, and the first redistribution line pattern extends in a horizontal direction, and
the first redistribution via has a tapered shape having a horizontal width increasing downwards in the vertical direction.

17. The semiconductor package as claimed in claim 11, wherein
a top surface of the first cover is substantially coplanar with a top surface of the first redistribution structure, and a top surface of the second cover is substantially coplanar with a top surface of the second redistribution structure.

18. A semiconductor package comprising:
a first redistribution structure comprising a first redistribution pattern and a first redistribution insulating layer at least partially surrounding the first redistribution pattern;
a first semiconductor chip disposed on the first redistribution structure;
a fourth semiconductor chip disposed on the first redistribution structure and spaced apart from the first semiconductor chip in a horizontal direction;
a first molding member surrounding the first semiconductor chip, the fourth semiconductor chip, and a side surface of the first redistribution structure;
a conductive pillar passing through the first molding member in a vertical direction;
a second redistribution structure disposed on the first molding member and comprising a second redistribution pattern and a second redistribution insulating layer at least partially surrounding the second redistribution pattern;
a second semiconductor chip disposed on the second redistribution structure;
a third semiconductor chip disposed on the second redistribution structure and spaced apart from the second semiconductor chip in the horizontal direction; and
a second molding member surrounding the second semiconductor chip, the third semiconductor chip, and a side surface of the second redistribution structure,
wherein a distance from the side surface of the first redistribution structure to a side surface of the first molding member is about 50 μm to about 200 μm,
a distance from the first surface of the second redistribution structure to a first surface of the second molding member is about 50 μm to about 200 μm, each of the first molding member and the second molding member includes an epoxy molding compound, and
each of the first redistribution insulating layer and the second redistribution insulating layer includes at least one of a photo-imageable dielectric (PID) or a photosensitive polyimide.

19. The semiconductor package as claimed in claim 18, wherein
the first redistribution pattern comprises a first redistribution via and a first redistribution line pattern, wherein the first redistribution via extends in the vertical direction, and the first redistribution line pattern extends in the horizontal direction, and
the first redistribution via has a tapered shape having a horizontal width increasing downwards in the vertical direction.

20. The semiconductor package as claimed in claim 18, wherein
the first redistribution pattern comprises a first redistribution via and a first redistribution line pattern, wherein the first redistribution via extends in the vertical direction, and the first redistribution line pattern extends in the horizontal direction,
a first bump and an underfill material layer are disposed between the first redistribution structure and the first semiconductor chip, and
the first redistribution via has a tapered shape having a horizontal width decreasing downwards in the vertical direction.
